(19) United States
(12) Patent Application Publication
(10) Pub. No.: US 2017/0179420 A1
(43) Pub. Date: Jun. 22, 2017

(54) 3D OLED SUBSTRATE AND FINE METAL MASK

(71) Applicant: Apple Inc., Cupertino, CA (US)

(72) Inventors: ChoongHo Lee, Santa Clara, CA (US); Jungmin Lee, Santa Clara, CA (US); Stephen S. Poon, Cupertino, CA (US)

(21) Appl. No.: 15/070,865

(22) Filed: Mar. 15, 2016

Related U.S. Application Data
(60) Provisional application No. 62/269,677, filed on Dec. 18, 2015.

(51) Int. Cl. H01L 51/50; H01L 51/00; H01L 51/56; H01L 27/32; H01L 51/52

(52) U.S. Cl. CPC H01L 51/5056; H01L 27/3246; H01L 51/5206; H01L 27/3211; H01L 51/5044; H01L 51/56; H01L 51/0023; H01L 2251/558; H01L 2251/308

(57) ABSTRACT

Organic light emitting diode (OLED) backplanes and fine metal masks (FMMs) are described. In an embodiment, an OLED backplane includes an array of raised bottom electrodes, and an FMM includes an array of pixel openings and an array of recesses. The FMM can be positioned over the backplane such that the pixel openings are over the raised bottom electrodes onto which a layer is to be evaporated, and the recesses are over the raised bottom electrodes that are to be protected from the evaporated species.

### CROSS-REFERENCE TO RELATED APPLICATIONS

This application claims the benefit of priority from U.S. Provisional Application No. 62/269,677, filed on Dec. 18, 2015, which is incorporated herein by reference.

### BACKGROUND

Field

Embodiments described herein relate to organic light emitting diode (OLED) displays and fine metal masks (FMMs) used on OLED production.

Background Information

State of the art displays for phones, tablets, computers, and televisions utilize glass substrates with thin film transistor (TFTs) to control transmission of backlight though pixels based on liquid crystals. More recently emissive displays such as those based on organic light emitting diodes (OLEDs) have been introduced as being more power efficient, and allowing each pixel to be turned off completely when displaying black.

An OLED display includes a matrix of pixels including multiple layers of organic films. For example, each OLED may include an electron transport layer, a hole transport layer, and an organic emission layer between the electron transport layer and the hole transport layer. The multiple layers may additionally include an electron injection layer and hole injection layer. Typically different organic emission layers are deposited for different color emission. A fine metal mask (FMM) is commonly used as a shadow mask during vapor deposition of the organic emission layers within the subpixels of an OLED display.

### SUMMARY

OLED backplanes, FMMs, and methods of OLED production are described. In an embodiment, a backplane used for OLED fabrication includes a substrate, an array of raised bottom electrodes on the substrate, and a pixel defining layer (PDL) on the substrate. In an embodiment, the PDL includes an array of openings over the array of raised bottom electrodes, and each raised bottom electrode in the array of raised bottom electrodes is thicker than the PDL.

In an embodiment, a FMM includes a frame with top side and a bottom surface, an array of pixel openings in the frame, and an array of recesses in the bottom surface of the frame laterally between the pixel openings. Each recess may include sidewalls and a top surface.

In an embodiment, a FMM is positioned over the display substrate such that an array of recesses in the FMM is directly over a first array of raised ground contacts, and an array of pixel openings in the FMM is directly over a second array of raised ground contacts. An array of organic emission layers can then be evaporated on the second array of raised contacts, or an intervening layer such as a hole transport layer.

### BRIEF DESCRIPTION OF THE DRAWINGS

FIG. 1 is a schematic top view illustration of a display backplane including spacers.

FIG. 2 is a schematic close-up cross-sectional side view illustration of an FMM positioned over a display backplane including spacers.

FIG. 3 is a schematic close-up cross-sectional side view illustration of an array of organic emission layers deposited on a display backplane including spacers.

FIG. 4 is a schematic close-up cross-sectional side view illustration of an FMM positioned over a display backplane including raised electrodes in accordance with an embodiment.

FIG. 5 is a perspective view of the bottom side of an FMM in accordance with an embodiment.

FIG. 6 is a perspective view of the bottom side of an FMM including spacers in accordance with an embodiment.

FIG. 7 is a schematic close-up cross-sectional side view illustration of an FMM including a spacer positioned over a display backplane including raised electrodes in accordance with an embodiment.

FIG. 8 is a schematic close-up cross-sectional side view illustration of an array of organic emission layers deposited on a display backplane including raised electrodes in accordance with an embodiment.

FIG. 9 is a schematic close-up cross-sectional side view illustration of multiple layer stack OLEDs in accordance with an embodiment.

### DETAILED DESCRIPTION

Embodiments describe OLED displays, FMMs, and methods of fabricating OLED displays. In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “top”, “bottom”, “over”, “to”, “between”, “spanning” and “on” as used herein may refer to a relative position of one layer with respect to other layers. One layer “over”, “spanning” or “on” another layer may be directly in contact with the other layer or may have one or more intervening layers. One layer “between” layers may be directly in contact with the layers or may have one or more intervening layers.

In one aspect, embodiments describe display backplanes and FMMs that may be used to mitigate color mixing between adjacent subpixels, and increase pixel density (pixels per inch, PPI) or aperture ratio. In an embodiment, a backplane includes a pixel defining layer (PDL) and an array of raised bottom electrodes (e.g anodes). The raised bottom electrodes may be thicker than the PDL. In an embodiment, an FMM includes an array of recesses in the bottom surface of the FMM frame laterally between the pixel openings. In operation, the FMM may be positioned over the display backplane so that the array of recesses are positioned over the array of raised electrodes. In such an arrangement, the bottom surface of the FMM can be located below the top surfaces of the raised electrodes (or the top surfaces of any intervening layers on the raised electrodes) during evaporation of the organic emission layers. This may inhibit the migration of the evaporated organic emission layers, and reduce potential color mixing even in the case of FMM misalignment.

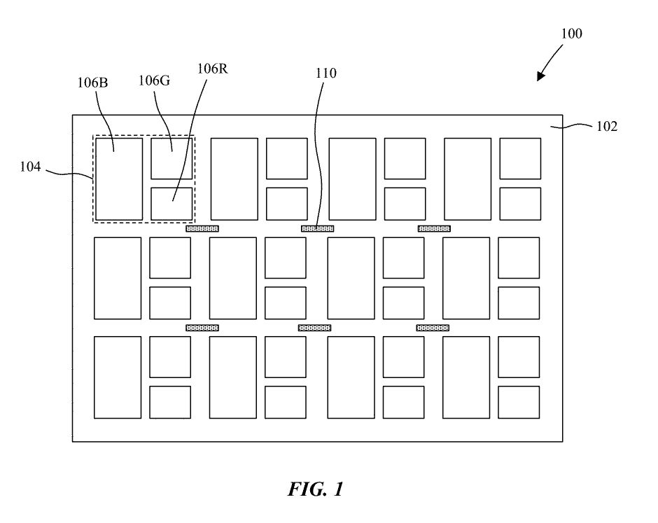

Referring now to FIG. 1 a cross-sectional side view illustration is provided of a display backplane 100. As illustrated, a display backplane 100 may include an array of pixels 104, and an array of spacers 110 formed on a substrate 102. Each pixel 102 may have a plurality of subpixels 106, each designed for a different color emission. The particular pixel 104 illustrated in FIG. 1 includes a blue-emitting subpixel 106B, a green-emitting subpixel 106G, and a red-emitting subpixel 106R for an RGB color arrangement, though this is exemplary and embodiments are not limited to a specific color arrangement.

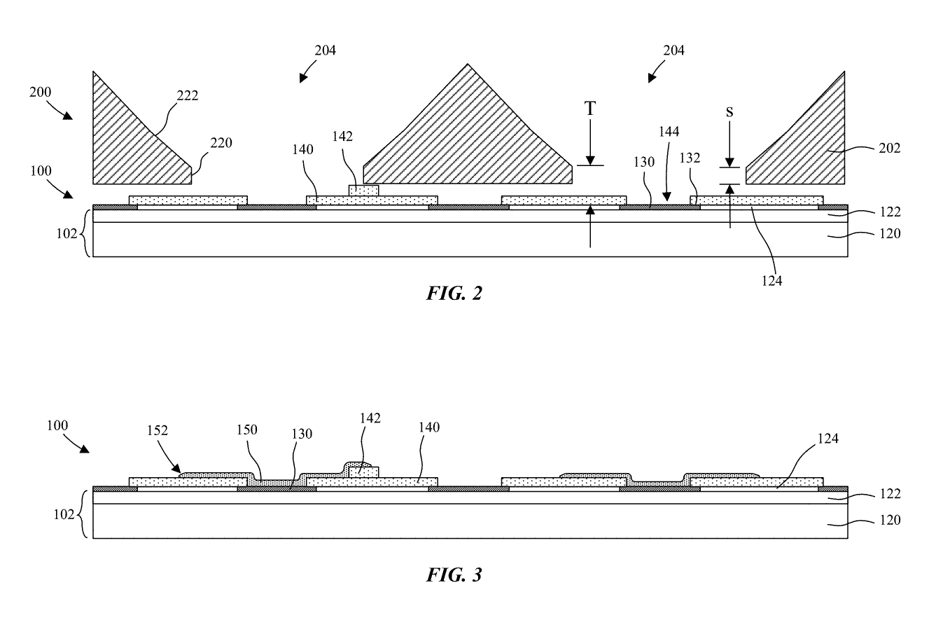

FIG. 2 is a schematic close-up cross-sectional side view illustration of an FMM 200 positioned over a display backplane 100 including spacers 142. As shown, the display backplane 100 may include a substrate 102. For example, substrate 102 may include a TFT substrate 120 and optionally a planarization layer 122. An array of electrodes 130 (e.g. anodes) may be formed on the planarization layer 122. A dielectric layer 124 may optionally separate the electrodes 130. A top surface of the electrodes 130 and dielectric layer 124 may optionally be planarized. A pixel defining layer (PDL) 140 including openings 144 is formed over the array of electrodes 130, and a plurality of spacers 142 may be formed on the PDL 140 or as part of the PDL. For example, the spacers 142 and PDL 140 may be formed of the same layer using a half tone lithography mask.

Still referring to FIG. 2, the FMM 200 includes a frame 200 and an array of pixel openings 204 in the frame. The pixel openings 204 may include sloped sidewalls 222, and a step 220 near a bottom surface 210 of the frame 200. As shown, the bottom surface 210 of the frame 200 may rest upon the plurality of spacers 142 during a deposition operation. During such a deposition operation (e.g. evaporation), the deposited species may potentially migrate underneath the bottom surface 210 of the FMM 200 and deposit as a shadow zone near the bottom electrodes 130 that are intended to be covered by the FMM 200, potentially causing color mixing. This may be attributed to the total thickness (T) of the PDL 140, spacers 142, and FMM step 220 height (S). FIG. 3 is a schematic close-up cross-sectional side view illustration of an array of organic emission layers 150 deposited on a display backplane 100 including spacers 142. As shown, edges 152 of the organic emission layers 150 may creep through the gaps between the FMM 200 and top surface of the PDL 140.

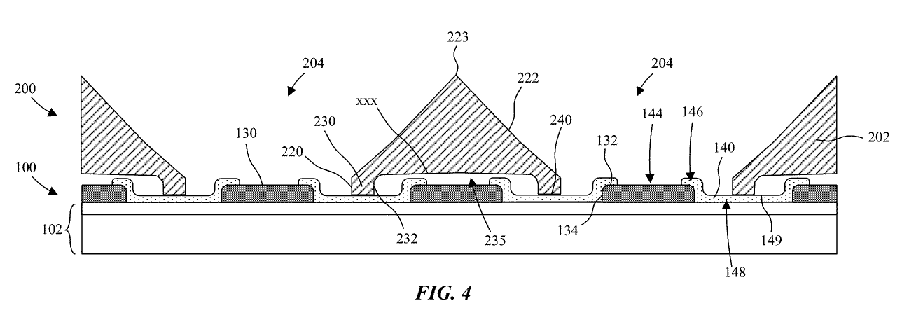

Referring now to FIG. 4, in accordance with embodiments an FMM 200 including recesses 235 is positioned over a display backplane 100 including raised bottom electrodes 130 (e.g. anodes). In the embodiment illustrated, the backplane 100 may include a substrate 102, an array of raised bottom electrodes 130 on the substrate 102, and a PDL 140 on the substrate 102. For example, substrate 102 may include a TFT substrate 120 and optionally a planarization layer 122. The PDL 140 includes an array of openings 144 over the array of raised bottom electrodes 130. Each raised bottom electrode 130 may correspond to a subpixel 106 (e.g. 106R, 106G, 106B), and be independently addressable. In the embodiment illustrated, each raised bottom electrode 130 in the array of raised bottom electrodes is thicker than the PDL 140.

The raised bottom electrodes 130 may be formed of a single layer, or a layer stack. For example, the raised bottom electrodes 130 may be formed of metals, conductive oxides, conductive polymers, and combinations thereof. For example, the raised bottom electrodes 130 may be formed of indium-tin-oxide (ITO), refractory metal, silver (Ag), or combinations thereof. In an embodiment, the raised bottom electrode 130 comprise layer stacks of ITO/Ag, ITO/Ag/ITO, ITO/Ag alloy/ITO. These combinations are exemplary, and embodiments are not so limited. For example, ITO may have a uniform work function so that the hold injection barrier is small to the OLED. Ag may function as a mirror layer.

In an embodiment, the raised bottom electrodes 130 are at least 2μm thick, such as 3μm thick. The raised bottom electrodes 130 may include top surfaces 132 and sidewalls 134. In an embodiment, the raised bottom electrodes 130 are formed by evaporation or sputtering, or a combination of evaporation or sputtering multiple layers. A PDL 140 may then be formed over the substrate 102 and patterned to form openings 144 over the top surfaces 132 of the raised bottom electrodes 130. The openings 144 may create injection region boundaries for the OLEDs that are formed on the raised bottom electrodes 130. In an embodiment, the PDL 140 is formed of a polymer, such as polyimide (PI), acrylic, or benzocyclobutene (BCB). In an embodiment, the PDL 140 is formed using a technique such as spin coating, though other techniques may be used. As shown, the coated PDL 140 is formed on the top surfaces 132 and sidewalls 134 of the raised bottom electrodes 130 and patterned to form openings 144. In accordance with embodiments, the PDL 140 is thinner than the raised bottom electrodes 130. For example, the PDL may be less than 1.5 μm thick, such as 1.0 μm thick. Due to the difference in thicknesses of the raised bottom electrodes 130 and the PDL 140, the PDL includes lip regions 146 around the raised bottom electrodes 130 on the top surfaces 132 of the raised bottom electrodes 130, and well regions 148 laterally between adjacent raised bottom electrodes 130. In an embodiment, a top surface 149 of the well regions 148 is below a top surface 132 of each raised bottom electrode 130.

Still referring to FIG. 4, in accordance with an embodiment an FMM 200 is positioned over the display backplane 100 with the recesses 235 in the FMM positioned directly over the raised bottom electrodes 130. The particular embodiment illustrated in FIG. 4 illustrates an FMM 200 positioned over the display backplane 100 prior to deposition of any of the OLED layers. In application, the formation of the OLED layers may include a number of different FMMs 200 and deposition operations. For example, the formation of an exemplary OLED may include the deposition of around 10-15 layers. Thus, while the specific embodiment illustrated in FIG. 4 shows the bottom surface 240 of the FMM residing on the top surface 149 of the PDL 140 well portions 148, this is exemplary and one or more layers may already be formed on top of the underlying structure.

In an embodiment, an FMM 200 includes a frame 202 with a top side 223 and a bottom surface 240. An array of pixel openings 204 are formed in the frame 202. For example, the pixel openings 204 extend between the top side and the bottom surface 240. In accordance with embodiments, an array of recesses 235 is formed in the bottom surface 240 of the frame 202 laterally between the pixel openings 204. Each recess 235 may include sidewalls 232 and a top surface 234. The sidewalls 232 for each recess 235 may form a complete loop. Each of the pixel openings 204 may include tapered sidewalls 222 so that the pixel openings 204 are wider at the top side 223 of the frame than at the bottom surface 240 of the frame 202. The tapered sidewalls 222 for each pixel openings 204 may additionally span directly over a plurality of recesses 235 in the bottom surface 240 of the frame 202.

In an embodiment, the FMM 200 additionally includes legs 230 (e.g. ridges) between the array of pixel openings 204 and the array of recesses 235. In an embodiment, the legs 230 (e.g. ridges) include sidewalls 220 that define the pixel openings 204 at the bottom surface 240. Alternatively, sidewalls 222 may extend all the way to the bottom surface 240. During use, the recesses 235 can be positioned directly over the raised bottom electrodes 130 with the legs 230 (e.g. ridges) laterally surrounding (e.g. completely laterally surrounding) the top surfaces 132 of the respective raised bottom electrodes 130 (or top surfaces of any overlying layers that may have already been deposited over the raised bottom electrodes 130).

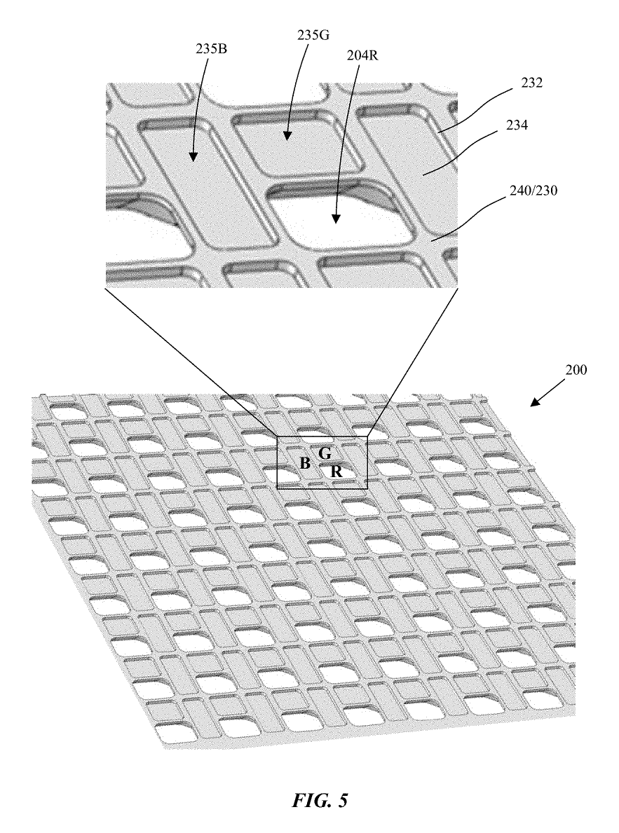

FIG. 5 is a perspective view of the bottom side of an FMM 200 in accordance with an embodiment. In the embodiment illustrated in FIG. 5, the bottom surface 240 of the frame 202 (e.g. bottom surface of the legs/ridges 230) may be a planar bottom surface in a grid pattern that is defined by the array of pixel openings 204 and the array of recesses 235. A close up illustration is additionally provided in FIG. 5 of a pixel area of the frame 202 including a recess 235B to be positioned over a raised bottom electrode 130 of a blue-emitting subpixel 106B, a recess 235G to be positioned over a raised bottom electrode 130 of a green-emitting subpixel 106B, and a pixel opening 204R to be positioned over a raised bottom electrode 130 of a red-emitting subpixel 106R. As shown, the arrays of recesses may include a first array of recesses (e.g. 235B) with a first top surface 234 with a first area, and a second array of recesses (e.g. 235G) with a second top surface 234 with a second area that is different from the first area. Similarly, the areas of the corresponding top surfaces 132 of the raised bottom electrodes 130 may be different.

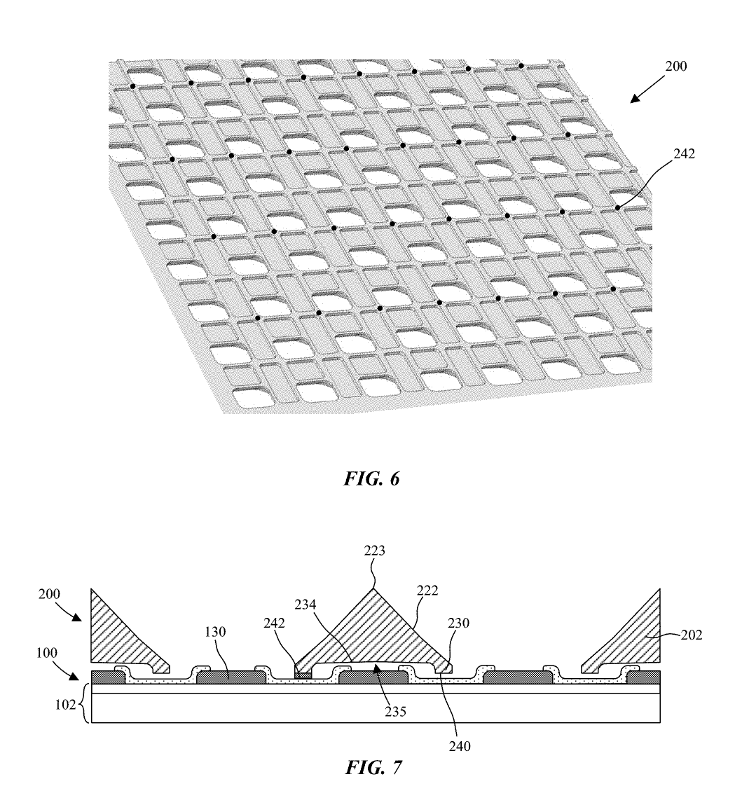

Referring now to FIGS. 6-7, in some embodiments the FMM 200 may include an array of spacers 242 protruding from the bottom surface 240 in a direction opposite of the array of recesses 235. The spacers 242 may be formed separately from the frame 202, or as part of the frame 202. FIG. 6 is a perspective view of the bottom side of an FMM 200 including spacers 242 in accordance with an embodiment. FIG. 7 is a schematic close-up cross-sectional side view illustration of an FMM 200 including a spacer 242 positioned over a display backplane 100 including raised electrodes 130 in accordance with an embodiment. In accordance with embodiments, the spacers 242 can be dispersed across the (e.g. planar) bottom surface 240 of the FMM 200. In one embodiment, the thickness of the spacers 242 is less than thickness of the raised bottom contacts 130. In such an arrangement, while a separation distance may be created between the bottom surface 240 of the FMM and underlying structure on the display backplane 100, the relative heights may create a substantial barrier to migration of the evaporated species.

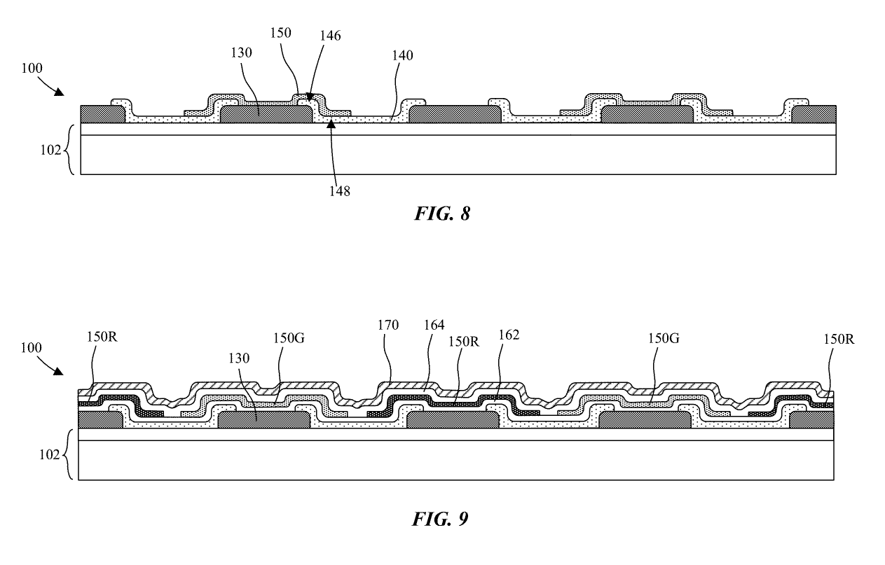

Referring now to FIG. 8 a schematic close-up cross-sectional side view illustration is provided of an array of organic emission layers 150 deposited on a display backplane 100 including raised electrodes 130 in accordance with an embodiment. The particular embodiment illustrated in FIG. 8 illustrates the formation of the organic emission layers 150 without other corresponding layers within an OLED. Accordingly, the organic emission layers 150 illustrated in FIG. 8 are illustrative of any layers formed using an FMM 200 in accordance with embodiments. In the particular embodiment illustrate the deposited organic emission layers 150 may be formed over the top surfaces 132 of the raised bottom electrodes 130, over the lip regions 146 and well regions 148 of the PDL 140.

FIG. 9 is a schematic close-up cross-sectional side view illustration of multiple layer stack OLEDs in accordance with an embodiment. The particular cross-section illustrated in FIG. 9 is exemplary of a cross-section taken along the red-emitting and green-emitting subpixels. As shown, arrays of organic emission layers 150R, 150G are formed over the array of bottom electrodes 130. While only red and green-emitting organic emission layers are illustrated, in an exemplary RGB system, the array of organic emission layers includes a first array of red-emitting organic emission layers, a second array of green-emitting organic emission layers, and a third array of blue-emitting organic emission layers.

In an embodiment, a common hole injection layer followed by common hole transport layer (illustrated together as 162) are formed over each of the raised bottom electrodes 130. Separate organic emission layers 150 are the specific raised bottom electrodes 130 for the corresponding subpixels. A common electron transport layer followed by common electron injection layer (illustrated together as 164) are then formed over the arrays of organic emission layers 150. A common top electrode layer (e.g. cathode) may then be formed over the common electron injection layer. The top electrode layer may be formed a transparent conductive oxide, such as ITO, or a transparent conductive polymer.

In an embodiment, a method of forming an OLED display comprises positioning an FMM over a display substrate that includes a first array of raised ground contacts and a second array of raised ground contacts. The FMM may include a frame, an array of pixel openings in the frame, and an array of recesses in the bottom surface of the frame laterally between the pixel openings. In the embodiment, positioning the FMM over the display substrate includes positioning the array of recesses directly over the first array of raised ground contacts, and positioning the array of pixel openings directly over the second array of raised ground contacts. An array of organic emission layers is then evaporated on the second array of raised ground contacts.

Prior to positioning the FMM over the display substrate, a PDL may be formed on the display substrate and patterned to form an opening over each raised ground contact. Each raised ground contact may be thicker than the PDL. In an embodiment, the FMM may include an array of spacers on a bottom surface of the FMM. Each raised ground contact may be thicker than each spacer. One or more layers may have already been formed over the arrays of raised ground contacts prior to evaporating the array of organic emission layers. In an embodiment, positioning the FMM over the display substrate includes resting the FMM on a hole transport layer.

In utilizing the various aspects of the embodiments, it would become apparent to one skilled in the art that combinations or variations of the above embodiments are possible for forming a display backplane and FMM. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

1-7. (canceled)

8. A fine metal mask comprising:
a frame including a top side and a bottom surface;
an array of pixel openings in the frame; and
an array of recesses in the bottom surface of the frame laterally between the pixel openings, each recess including sidewalls and a top surface.

9. The fine metal mask of claim 8, wherein each pixel opening includes tapered sidewalls so that the pixel opening is wider at the top side of the frame than the bottom surface of the frame.

10. The fine metal mask of claim 9, wherein the tapered sidewalls for each pixel opening at least partially span directly over a plurality of the recesses in the bottom surface of the frame.

11. The fine metal mask of claim 10, wherein the sidewalls for each recess form a complete loop.

12. The fine metal mask of claim 10, wherein the bottom surface is a planar bottom surface in a grid pattern defined by the array of pixel openings and the array of recesses.

13. The fine metal mask of claim 12, further comprising an array of spacers protruding from the bottom surface in a direction opposite of the array of recesses.

14. The fine metal mask of claim 12, wherein the array of recesses includes a first array of recesses each including a first top surface with a first area, and a second array of recesses each including a second top surface with a second area, wherein the first area and the second area are different.

15. A method comprising:
positioning a fine metal mask (FMM) over a display substrate;
wherein the display panel comprises a first array of raised ground contacts and a second array of raised ground contacts;
wherein the FMM includes a frame that includes a top side and a bottom surface, an array of pixel openings in the frame, and an array of recesses in the bottom surface of the frame laterally between the pixel openings, each recess including sidewalls and a top surface;
wherein positioning the FMM over the display substrate comprises positioning the array of recesses directly over the first array of raised ground contacts, and positioning the array of pixel openings directly over the second array of raised ground contacts; and
evaporating an array of organic emission layers on the second array of raised ground contacts.

16. The method of claim 15, further comprising forming a pixel defining layer on the display substrate, and patterning the pixel defining layer to form an opening over each raised ground contact.

17. The method of claim 16, wherein the each raised ground contact is thicker than the pixel defining layer.

18. The method of claim 16, wherein the FMM comprises an array of spacers on a bottom surface of the FMM, and each raised ground contact is thicker than each spacer.

19. The method of claim 15, wherein positioning the FMM over the display substrate comprises resting the FMM on a hole transport layer.
